(19) United States
(12) Patent Application Publication
(10) Pub. No.: US 2005/0124160 A1
(43) Pub. Date: Jun. 9, 2005

(54) Novel multi-gate formation procedure for gate oxide quality improvement

(75) Inventors: Yi Song Chiu, Hsin-chu (TW); Chung Long Cheng, Hsin-chu (TW); Wen Ting Tsai, Hsin-chu (TW); Jao Sheng Huang, Hsin-chu (TW); Chen Hsiang Leu, Hsin-chu (TW)

Correspondence Address: DUANE MORRIS, LLP;IP DEPARTMENT, ONE LIBERTY PLACE, PHILADELPHIA, PA, 19103-7396, US

(73) Assignee: Taiwan Semiconductor Manufacturing Co.

(21) Appl. No.: 10/729,458

(22) Filed: Dec. 5, 2003

(51) Int. Cl. B32B 3/02; H01L 21/302; H01L 21/461

(52) U.S. Cl. 438/689

(57) ABSTRACT

A process for forming a semiconductor device with multiple gate insulator thicknesses, wherein exposed surfaces of a semiconductor substrate are protected during a photoresist stripping procedure, has been developed. After growth of an insulator layer on the entire surface of a semiconductor substrate portions of the insulator layer not covered by a photoresist masking shape are selectively removed. A two step photoresist removal procedure is then employed initiating with an ozone water cycle which partially removes the photoresist shape while forming a thin silicon oxide layer on the portions of bare semiconductor surface. A acid-hydrogen peroxide mixture (SPM), is then used to complete the photoresist removal procedure including removal of photoresist residues, with the thin silicon oxide layer formed during the ozone water cycle protecting the previously bare underlying semiconductor surface. An oxidation procedure is then performed allowing a first gate insulator layer to be formed incorporating the original insulator layer, and allowing a thinner, second gate insulator layer to be obtained, incorporating the thin silicon oxide layer.

### BACKGROUND OF THE INVENTION

(1) Field of the Invention

The present invention relates to methods used to fabricate semiconductor devices and more specifically to a method used to form multi-gate oxide layers on a semiconductor substrate.

(2) Description of Prior Art

Specific semiconductor devices designed to provide dual voltage applications, particularly for the deep sub-micron technology, are achieved using two different gate insulator layer thicknesses, sometimes referred to as a dual gate oxide technology. However the process sequences used to form dual gate insulator layers can result in unwanted device leakage phenomena. For example a process used to form two different gate insulator layers entails growth of a first insulator layer on the entire surface of a semiconductor substrate, followed by removal of the first insulator layer from a second portion of the semiconductor substrate, so that the second portion of semiconductor substrate can be available to subsequently accommodate a second insulator layer. This requires masking of the first insulator layer located on a first portion of the semiconductor substrate during the removal procedure, usually accomplished using a photoresist shape as mask. However the procedure used to subsequently remove the photoresist mask from the underlying first insulator layer can result in damage to the now exposed second portion of semiconductor substrate, resulting in a second insulator layer of inferior quality grown on the second portion of semiconductor substrate.

The present invention will describe a novel process sequence in which dual gate oxide layers are employed. The present invention however will describe a process for removal of a photoresist masking shape in which a bare portion of semiconductor surface to be used to accommodate a subsequently grown gate oxide layer, is not subjected to damaging components of the photoresist stripping procedure. Prior art such as Ohmi et al in U.S. Pat. No. 5,858,106, Tsuji in U.S. Pat. No. 5,454,901, and Chung et al in U.S. Pat. No. 6,513,538 B2, describe methods of cleaning surfaces of semiconductor materials, however none of the above prior art feature the novel procedure described in the present invention in which the bare portion of semiconductor surface is not exposed to damaging wet chemical components of the photoresist strip procedure.

### SUMMARY OF THE INVENTION

It is an object of this invention to fabricate a device featuring two or more gate insulator layer thicknesses on a semiconductor substrate.

It is another object of this invention to use a photoresist shape to protect a first gate insulator layer located on first portions of a semiconductor substrate, during the wet etch removal of the same first insulator layer from second portions of a semiconductor substrate, wherein the second portions of the semiconductor substrate are to be used to subsequently accommodate a second insulator layer.

It is still another object of this invention to protect the bare, second portions of the semiconductor substrate from damaging components of the photoresist shape removal procedure via the addition of a ozone water component to the photoresist strip recipe.

In accordance with the present invention a method of forming multiple gate insulator layers on the same semiconductor substrate wherein the bare surface of a second section of semiconductor substrate is protected from a procedure used to remove a photoresist masking shape from a gate insulator layer overlying a first section of the semiconductor substrate, is described. After growth of a first insulator layer on the entire surface of a semiconductor substrate a photoresist shape is formed on a portion of the first insulator layer allowing a wet etch procedure to remove the unprotected portion of the first gate insulator layer exposing a bare semiconductor surface in a second section of the semiconductor substrate. Removal of the photoresist masking shape is next accomplished using an ozone water chemistry followed by a hydrogen peroxide-sulfuric acid procedure. The ozone water cycle results in formation of a thin, saturated oxide layer on the exposed surface of semiconductor substrate, while partially removing the photoresist masking shape. The subsequent sulfuric acid-hydrogen peroxide procedure completely removes the remaining photoresist masking shape with the saturated oxide layer protecting the semiconductor surface from the sulfuric acid-hydrogen peroxide procedure. A second insulator layer is grown on the bare semiconductor surface in the second section of semiconductor substrate, while the same insulator growth procedure results in an increase in thickness for the first insulator layer located in the first section of the semiconductor substrate.

### BRIEF DESCRIPTION OF THE DRAWINGS

The object and other advantages of this invention are best described in the preferred embodiments with reference to the attached drawings that include:

FIGS. 1-5, which schematically in cross-sectional style show the key stages of fabricating multiple gate insulator layers wherein the bare surface of a second section of semiconductor substrate, to be used to accommodate a subsequent second gate insulator layer, is protected from a procedure used to remove a photoresist masking shape from a first gate insulator layer overlying a first section of the semiconductor substrate.

### DESCRIPTION OF THE PREFERRED EMBODIMENTS

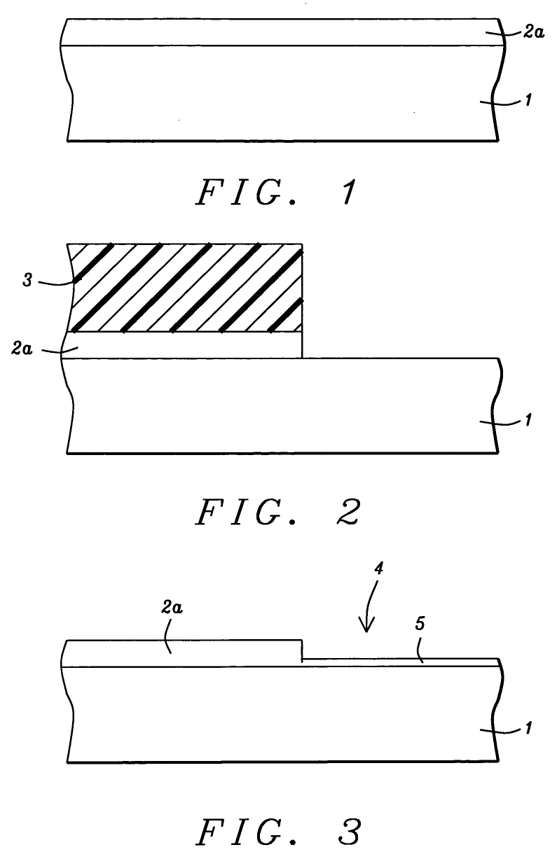

The method of fabricating multiple gate insulator layers on the same semiconductor substrate wherein the bare surface of a second section of semiconductor substrate, to be used to accommodate a subsequent second gate insulator layer, is protected from a procedure used to remove a photoresist masking shape from a first gate insulator layer overlying a first section of the semiconductor substrate, will now be described in detail. Semiconductor substrate 1, comprised of single crystalline silicon featuring a <100> crystallographic orientation, is used. Gate insulator layer 2a, shown schematically in FIG. 1, comprised of silicon dioxide, is thermally grown in an oxygen-steam ambient at a thickness between about 10 to 200 Angstroms. Photoresist shape 3, is formed on a portion of gate insulator layer 2a, allowing the exposed portion of gate insulator layer 2a, to be removed via wet etch procedures featuring the use of either a buffered hydrofluoric (BHF) acid solution, or a dilute hydrofluoric (DHF) acid solution. If desired the exposed portion of gate insulator 2a, can be removed via dry etch procedures using CHF₃ as a selective etchant for gate insulator layer 2a. The result of this procedure is schematically shown in FIG. 2.

Removal of photoresist shape 3, is next addressed and schematically described in FIG. 3. To insure complete removal of photoresist shape 3, including complete removal of any photoresist residue, strong organic solvents are needed. One such solvent is a sulfuric acid-hydrogen peroxide mixture (SPM), when applied at a temperature between about 110 to 140° C., completely removes photoresist and photoresist residues. However the exposure of the portion of bare semiconductor substrate, the portion recently exposed by removal of overlying gate insulator layer 2a, the portion of semiconductor substrate to be subsequently used to accommodate a second gate insulator layer, can be damaged during the SPM procedure. The damaged surface of the semiconductor substrate can deleteriously influence the quality of the gate insulator layer subsequently grown on this damaged material in terms of degraded gate insulator integrity as well as increased hot carrier phenomena. Therefore to successfully remove photoresist masking shapes and photoresist residues without damaging exposed portions of a semiconductor substrate, a novel sequence for accomplishing the above is used.

A two stage procedure is now employed to remove photoresist shape 3. First ozone gas 4, dissolved in de-ionized water is used to partially remove photoresist shape 3, however more importantly forming thin silicon oxide layer 5, on the exposed portions of semiconductor substrate 1. The conditions used for the ozone cycle, performed at a temperature between about 20 to 50° C., employing between about 5 to 30 ppm ozone, results in silicon oxide layer 5, at a thickness between about 8 to 10 Angstroms being formed on the exposed portions of semiconductor substrate 1. Next complete removal of photoresist shape 3, as well as any photoresist residues, are accomplished via of SPM employed at a temperature between about 110 to 150° C. Thin silicon oxide layer 5, protected the previously bare portions of semiconductor substrate 1, during the SPM procedure. The result of the two stage photoresist removal procedure is schematically shown in FIG. 3.

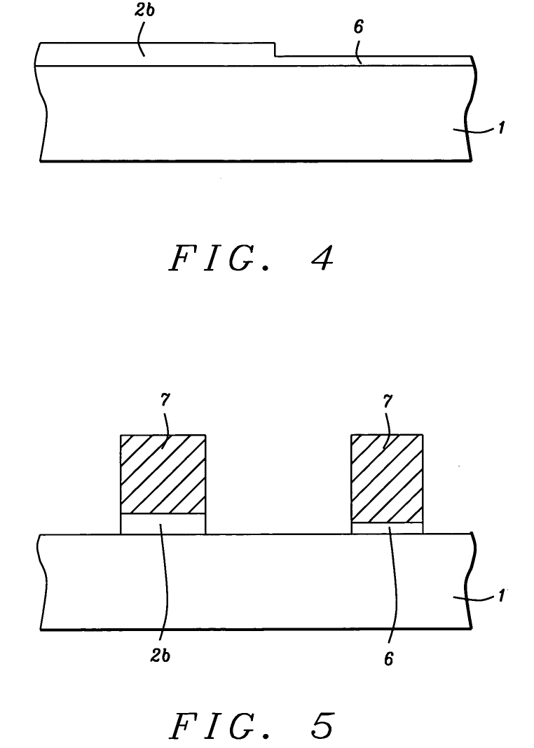

Formation of gate insulator layer 6, or the thin gate insulator layer component of a dual gate insulator device, is next addressed and schematically described in FIG. 4. A thermal oxidation procedure is performed in an oxygen-steam ambient at a temperature between about 800 to 1050° C., resulting in the growth of silicon dioxide gate insulator layer 6, consuming the thin silicon oxide layer 5, previously formed during the ozone photoresist removal procedure. The thickness of gate insulator layer 6, shown schematically in FIG. 4, is between about 10 to 100 Angstroms. The same thermal oxidation procedure results in additional growth of exposed gate insulator layer 2a, resulting in silicon dioxide, gate insulator layer 2b, now at a thickness between about 15 to 200 Angstroms.

Conductive gate structures 7, shown schematically in FIG. 5, are next defined on both gate insulator layers. A conductive layer such as doped polysilicon or metal silicide is formed on the underlying gate insulator layers at a thickness between about 1000 to 3000 Angstroms. A photoresist shape, not shown in the drawings, is used as an etch mask to allow an anisotropic reactive ion etching procedure to define conductive gate structures 7. The anisotropic reactive ion etching procedure is performed using Cl₂ or SF₆ as a selective etchant for the conductive layer with the dry etch procedure selectively terminating at the appearance of the top surface of the gate insulator layers. The photoresist shape used to define conductive gate structures 7, is removed via plasma oxygen ashing and wet clean procedures, with a BHF component of the wet clean procedure allowing portions of gate insulator layer 2b, and the portions of gate insulator layer 6, not covered by conductive gate structures 7, to be selectively removed.

While this invention has been particularly shown and described with reference to, the preferred embodiments thereof, it will be understood by those skilled in the art that various changes in form and details may be made without departing from the spirit and scope of this invention.

1. A method of forming multiple gate insulator layers on a semiconductor substrate, comprising the steps of:
forming a first insulator layer on said semiconductor substrate;
forming a photoresist shape on a first section of said first insulator layer;
removing second section of said first insulator layer exposing a bare first section of said semiconductor substrate;
performing a first photoresist removal procedure resulting in partial removal of said photoresist shape and forming a second insulator layer on said bare first section of said semiconductor substrate;
performing a second photoresist removal procedure completely removing said photoresist shape;
performing a procedure to convert said first insulator layer located on a second section of said semiconductor substrate, to a first gate insulator layer, and to convert said second insulator layer to a second gate insulator layer, wherein the thickness of said first gate insulator is different than the thickness of said second gate insulator layer; and forming a first conductive gate structure on said first gate insulator layer and forming a second conductive gate structure on said second gate insulator layer.

2. The method of claim 1, wherein said first insulator layer is a silicon dioxide layer, at a thickness between about 10 to 200 Angstroms.

3. The method of claim 1, wherein removal of said second section of said first insulator layer is accomplished via use of a buffered hydrofluoric (BHF) acid solution.

4. The method of claim 1, wherein said first photoresist removal procedure is performed using ozone water.

5. The method of claim 1, wherein said second insulator layer formed on said second section of said semiconductor substrate, is a silicon oxide layer at a thickness between about 8 to 10 Angstroms.

6. The method of claim 1, wherein said second photoresist removal procedure is performed using a sulfuric acid-hydrogen peroxide mixture (SPM).

7. The method of claim 1, wherein said second photoresist removal procedure is performed at a temperature between about 110 to 150° C.

8. The method of claim 1, wherein said procedure used to convert said first insulator layer and said second insulator layer to gate insulator layers is an oxidation procedure, performed in an oxygen-steam ambient.

9. The method of claim 1, wherein said procedure used to convert said first insulator layer and said second insulator layer to gate insulator layers is an oxidation procedure, performed at a temperature between about 800 to 1050° C.

10. The method of claim 1, wherein said first gate insulator layer is a silicon dioxide layer, at a thickness between about 15 to 200 Angstroms.

11. The method of claim 1, wherein said second gate insulator layer is a silicon dioxide layer, at a thickness between about 10 to 100 Angstroms.

12. The method of claim 1, wherein said first conductive gate structure and said second conductive gate structure are comprised of doped polysilicon.

13. The method of claim 1, wherein said first conductive gate structure and said second conductive gate structure are comprised of metal silicide.

14. A method of forming a semiconductor device on a semiconductor substrate featuring multiple gate insulator thicknesses comprising the steps of:
forming a first silicon oxide layer on entire surface of said semiconductor substrate;
forming a photoresist shape on a first section of said first silicon oxide layer, in a region overlying a first section of said semiconductor substrate;
removing second section of said first silicon oxide layer exposing a bare second section of said semiconductor substrate;
performing an ozone containing mixture procedure to partially remove said photoresist shape and to form a second silicon oxide layer on said bare second section of said semiconductor substrate;
performing a sulfuric acid-hydrogen peroxide mixture (SPM) procedure, to completely remove said photoresist shape; and
performing an oxidation procedure to convert said first silicon oxide layer to a first gate insulator layer on said first section of said semiconductor substrate, and to convert said second silicon oxide layer to a second gate insulator layer, wherein the thickness of said first gate insulator is greater than the thickness of said second gate insulator layer; and
forming a first conductive gate structure on said first gate insulator layer and forming second conductive gate structure on said second gate insulator layer.

15. The method of claim 14, wherein said first silicon oxide layer is a silicon dioxide layer, at a thickness between about 10 to 200 Angstroms.

16. The method of claim 14, wherein removal of said second section of said first silicon oxide layer is accomplished via use of a buffered hydrofluorc (BHF) acid solution.

17. The method of claim 14, wherein removal of said second section of said first silicon oxide layer is accomplished via dry etching procedures using CHF₃ as a selective etchant for said first silicon oxide layer.

18. The method of claim 14, wherein ozone water procedure is performed at a temperature between about 20 to 50° C.

19. The method of claim 14, wherein the thickness of said second silicon oxide layer formed on said second section of said semiconductor substrate, is between about 8 to 10 Angstroms.

20. The method of claim 14, wherein said sulfuric acid-hydrogen peroxide mixture (SPM) procedure is performed at a temperature between about 110 to 150° C.

21. The method of claim 14, wherein said oxidation procedure is performed at a temperature between about 800 to 1050° C.

22. The method of claim 14, wherein said first gate insulator layer is a silicon dioxide layer, at a thickness between about 15 to 200 Angstroms.

23. The method of claim 14, wherein said second gate insulator layer is a silicon dioxide layer, at a thickness between about 10 to 100 Angstroms.

24. The method of claim 14, wherein said first conductive gate structure and said second conductive gate structure are comprised of doped polysilicon.

25. The method of claim 14, wherein said first conductive gate structure and said second conductive gate structure are comprised of metal silicide.
